(19) United States
(12) Patent Application Publication
(10) Pub. No.: US 2025/0323053 A1
(43) Pub. Date: Oct. 16, 2025

(54) CONTROLLED ETCH OF SILICON NITRIDE MATERIAL

(71) Applicant: Applied Materials, Inc., Santa Clara, CA (US)

(72) Inventors: Sonam Dorje Sherpa, San Ramon, CA (US); Alok Ranjan, San Ramon, CA (US)

(73) Assignee: Applied Materials, Inc., Santa Clara, CA (US)

(21) Appl. No.: 18/636,684

(22) Filed: Apr. 16, 2024

(51) Int. Cl. H01L 21/311

(52) U.S. Cl. CPC H01L 21/31116

(57) ABSTRACT

Exemplary semiconductor processing methods may include flowing a fluorine-containing precursor into a processing region of a semiconductor processing chamber. A substrate may be positioned within the processing region. The substrate may include a layer of a silicon-and-nitrogen-containing material. The methods may include contacting the substrate with the fluorine-containing precursor. The contacting may form a fluorinated portion of the silicon-and-nitrogen-containing material. The methods may include flowing an inert precursor into the processing region of the semiconductor processing chamber. The methods may include forming plasma effluents of the inert precursor. The methods may include contacting the substrate with the plasma effluents of the inert precursor. The contacting may remove the fluorinated portion of the silicon-and-nitrogen-containing material. The method may be performed at a chamber operating temperature of less than or about 20° C.

### TECHNICAL FIELD

The present technology relates to semiconductor processes and equipment. More specifically, the present technology relates to etching silicon nitride material.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

Etch processes may be termed wet or dry based on the materials used in the process. A wet HF etch preferentially removes silicon oxide over other dielectrics and materials. However, wet processes may have difficulty penetrating some constrained trenches and also may sometimes deform the remaining material. Dry etches produced in local plasmas formed within the substrate processing region can penetrate more constrained trenches and exhibit less deformation of delicate remaining structures. However, local plasmas may damage the substrate through the production of electric arcs as they discharge.

Thus, there is a need for improved systems and methods that can be used to produce high quality devices and structures. These and other needs are addressed by the present technology.

### SUMMARY

Exemplary semiconductor processing methods may include flowing a fluorine-containing precursor into a processing region of a semiconductor processing chamber. A substrate may be positioned within the processing region. The substrate may include a layer of a silicon-and-nitrogen-containing material. The methods may include contacting the substrate with the fluorine-containing precursor. The contacting may form a fluorinated portion of the silicon-and-nitrogen-containing material. The methods may include flowing an inert precursor into the processing region of the semiconductor processing chamber. The methods may include forming plasma effluents of the inert precursor. The methods may include contacting the substrate with the plasma effluents of the inert precursor. The contacting may remove the fluorinated portion of the silicon-and-nitrogen-containing material. The method may be performed at a chamber operating temperature of less than or about 20° C.

In some embodiments, the fluorine-containing precursor may be or include hydrogen fluoride (HF). The processing region may be maintained carbon-free while flowing the fluorine-containing precursor and contacting the substrate with the fluorine-containing precursor. The substrate may further include a patterned mask material overlying the layer of the silicon-and-nitrogen-containing material. The methods may include, prior to flowing the inert precursor, halting a flow of the fluorine-containing precursor after a first period of time. The methods may include purging the processing region with a purge precursor. The first period of time may be less than or about 5 minutes. The processing region may be maintained plasma-free while flowing the fluorine-containing precursor and contacting the substrate with the fluorine-containing precursor. The inert precursor may be or include argon. The methods may include applying a bias power while contacting the substrate with the plasma effluents of the inert precursor. The bias power may be less than or about 150 V. The methods may be performed at a chamber operating pressure of less than or about 1 Torr. The methods may be performed at a chamber operating temperature of less than or about −50° C.

Some embodiments of the present technology may encompass semiconductor processing methods. The methods may include i) flowing a fluorine-containing precursor into a processing region of a semiconductor processing chamber. A substrate may be positioned within the processing region. The substrate may include a layer of a silicon-and-nitrogen-containing material. The methods may include ii) contacting the layer of the silicon-and-nitrogen-containing material with the fluorine-containing precursor. The contacting may form a fluorinated portion of the layer of the silicon-and-nitrogen-containing material. The contacting may be performed plasma-free. The methods may include iii) halting a flow of the fluorine-containing precursor. The methods may include iv) flowing an inert precursor into the processing region of the semiconductor processing chamber. The methods may include v) forming plasma effluents of the inert precursor. The methods may include vi) contacting the substrate with the plasma effluents of the inert precursor. The contacting may remove the fluorinated portion of the layer of the silicon-and-nitrogen-containing material. The methods may include vii) repeating operations i) through vi) for at least a second cycle.

In some embodiments, the fluorine-containing precursor may further include hydrogen. A flow rate of the fluorine-containing precursor may be less than or about 500 sccm. Operations i) through vi) may be repeated for at least ten cycles. The methods may be performed at a chamber operating temperature of less than or about −40° C.

Some embodiments of the present technology may encompass semiconductor processing methods. The methods may include flowing a fluorine-containing precursor into a processing region of a semiconductor processing chamber. A substrate may be positioned within the processing region. The substrate may include a layer of a silicon-and-nitrogen-containing material. The methods may include contacting the substrate with the fluorine-containing precursor for a first period of time. The contacting may form a fluorinated portion of the silicon-and-nitrogen-containing material. The fluorinated portion of the silicon-and-nitrogen-containing material may be characterized by a thickness of greater than or about 50 nm. The methods may include halting a flow of the fluorine-containing precursor into the processing region subsequent the first period of time. The methods may include flowing an inert precursor into the processing region of the semiconductor processing chamber. The methods may include forming plasma effluents of the inert precursor. The methods may include contacting the substrate with the plasma effluents of the inert precursor for a second period of time. The contacting may remove the fluorinated portion of the silicon-and-nitrogen-containing material.

In some embodiments, the first period of time may be less than or about 60 seconds and the second period of time may be less than or about 30 seconds.

Such technology may provide numerous benefits over conventional systems and techniques. For example, the processes may etch silicon-and-nitrogen-containing materials, such as features into silicon-and-nitrogen-containing materials, within semiconductor structures. Additionally, the processes may etch materials without greenhouse gases and/or polymer formation and may uniformly etch through silicon-and-nitrogen-containing materials. These and other embodiments, along with many of their advantages and features, are described in more detail in conjunction with the below description and attached figures.

### BRIEF DESCRIPTION OF THE DRA WINGS

A further understanding of the nature and advantages of the disclosed technology may be realized by reference to the remaining portions of the specification and the drawings.

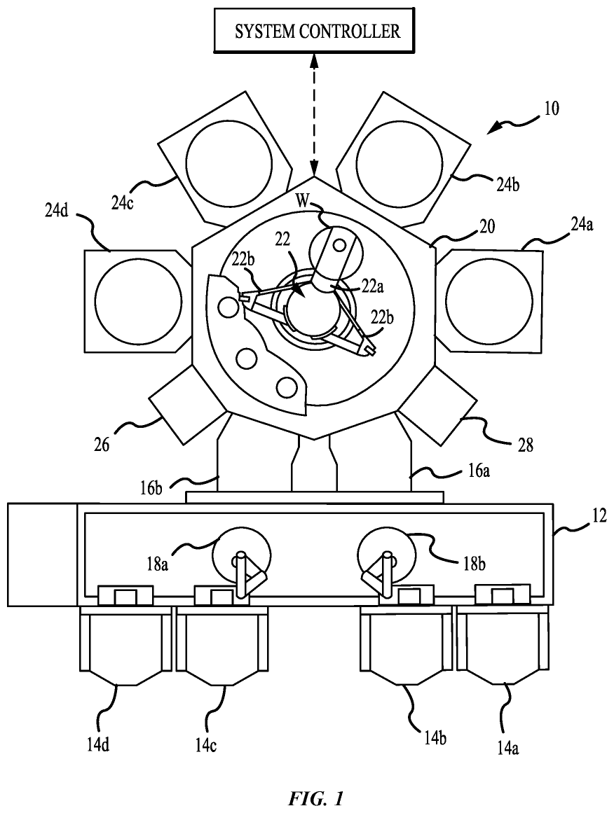

FIG. 1 shows a top plan view of one embodiment of an exemplary processing system according to some embodiments of the present technology.

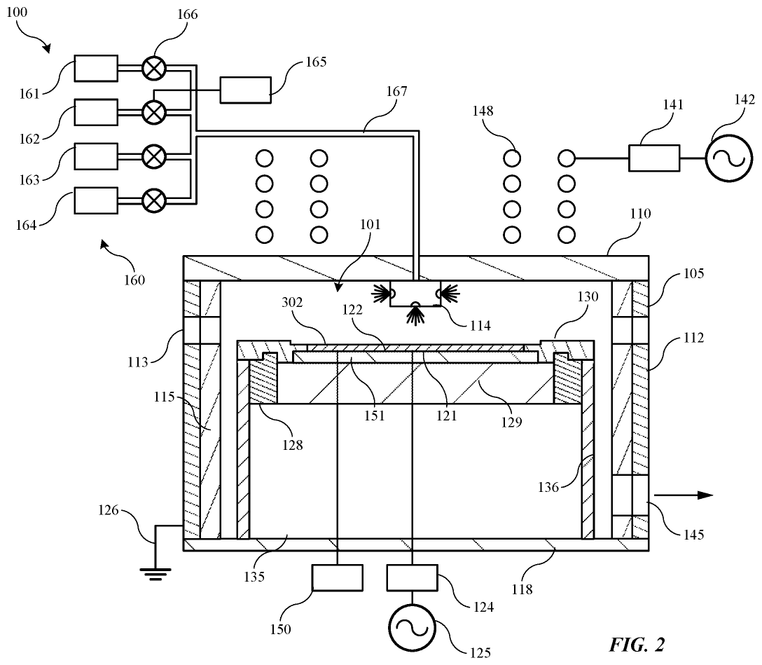

FIG. 2 shows a schematic cross-sectional view of an exemplary processing chamber according to some embodiments of the present technology.

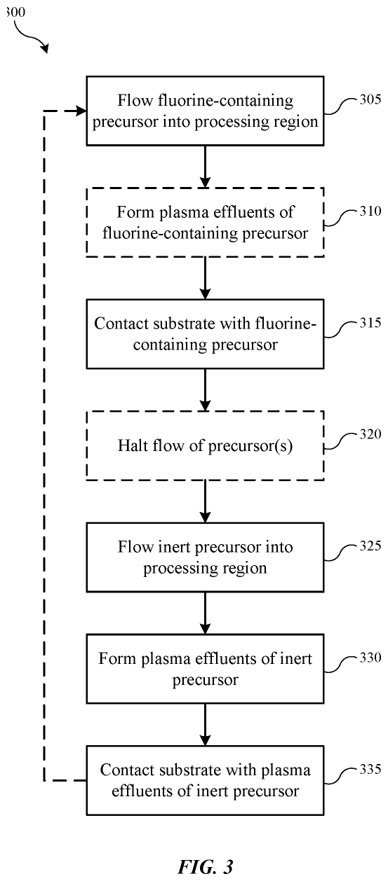

FIG. 3 shows exemplary operations in a method according to some embodiments of the present technology.

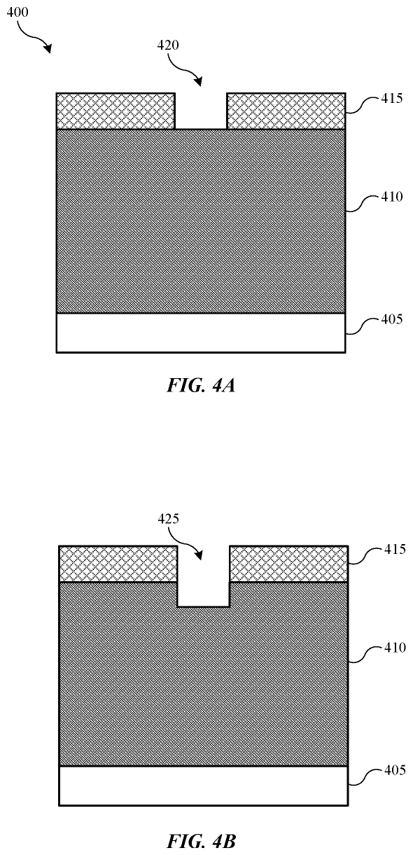

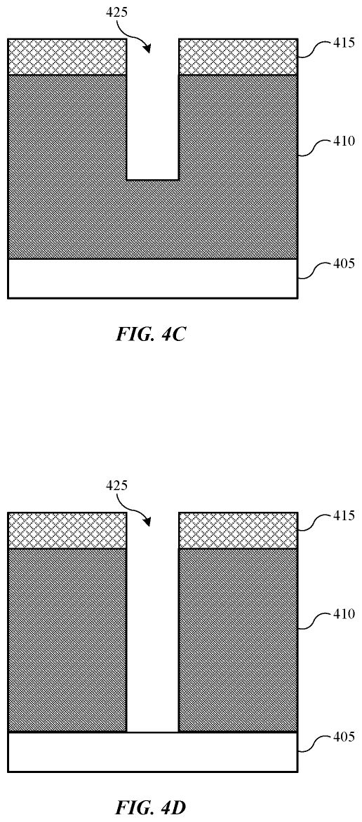

FIGS. 4A-4D show cross-sectional views of substrates being processed according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

In transitioning from 2D NAND to 3D NAND, many process operations are modified from vertical to horizontal operations. Additionally, as 3D NAND structures grow in the number of cells being formed, the aspect ratios of holes, trenches, and other structures increase, sometimes dramatically. During 3D NAND processing, or other memory and/or logic processing, layers silicon-and-nitrogen-containing materials may be present in intermediate structures. These silicon-and-nitrogen-containing materials may have a variety of operations performed to fabricate final devices. For example, one or more holes or trenches may be etched into the silicon-and-nitrogen-containing materials.

Many conventional technologies utilize an etch process that passivates sidewalls of the holes or trenches. By passivating the sidewalls, a uniform profile of the holes or trenches may be maintained, and lateral etching may be minimized. However, formation of the passivation material on the sidewalls, which may be a polymeric material, may not be uniform throughout a depth of the hole or trench. Accordingly, conventional technologies may suffer from pattern loading and/or bending. Further, conventional technologies forming polymeric passivation material may deposit polymeric material on the wafer bevel, which may result in arcing.

Conventional technologies may also utilize greenhouse gases, which may introduce environmental concerns.

The present technology overcomes these issues by performing an etch process using cyclic exposure first to a fluorine-containing precursor and second to an inert precursor. The etch process may be formed at a low temperature that increases directionality of the etch without the need for polymeric passivation material. Due to the high directionality of the etch, issues with hole or trench profile are reduced and/or eliminated. Additionally, arcing is mitigated since polymeric material is not being inadvertently deposited on the wafer bevel. Finally, the present technology may not require the use of greenhouse gases, reducing and/or eliminating environmental concerns associated with conventional technologies.

Although the remaining disclosure will routinely identify specific etching processes utilizing the disclosed technology, it will be readily understood that the systems and methods are equally applicable to deposition and cleaning processes as may occur in the described chambers. Accordingly, the technology should not be considered to be so limited as for use with etching processes or chambers alone. Moreover, although an exemplary chamber is described to provide foundation for the present technology, it is to be understood that the present technology can be applied to virtually any semiconductor processing chamber that may allow the single-chamber operations described.

FIG. 1 shows a top plan view of one embodiment of a processing system 10 of deposition, etching, baking, and/or curing chambers according to embodiments. The tool or processing system 10 depicted in FIG. 1 may contain a plurality of process chambers, 24a-d, a transfer chamber 20, a service chamber 26, an integrated metrology chamber 28, and a pair of load lock chambers 16a-b. The process chambers may include any number of structures or components, as well as any number or combination of processing chambers.

To transport substrates among the chambers, the transfer chamber 20 may contain a robotic transport mechanism 22. The transport mechanism 22 may have a pair of substrate transport blades 22a attached to the distal ends of extendible arms 22b, respectively. The blades 22a may be used for carrying individual substrates to and from the process chambers. In operation, one of the substrate transport blades such as blade 22a of the transport mechanism 22 may retrieve a substrate W from one of the load lock chambers such as chambers 16a-b and carry substrate W to a first stage of processing, for example, a treatment process as described below in chambers 24a-d. The chambers may be included to perform individual or combined operations of the described technology. For example, while one or more chambers may be configured to perform a deposition or etching operation, one or more other chambers may be configured to perform a pre-treatment operation and/or one or more post-treatment operations described. Any number of configurations are encompassed by the present technology, which may also perform any number of additional fabrication operations typically performed in semiconductor processing.

If the chamber is occupied, the robot may wait until the processing is complete and then remove the processed substrate from the chamber with one blade 22a and may insert a new substrate with a second blade. Once the substrate is processed, it may then be moved to a second stage of processing. For each move, the transport mechanism 22 generally may have one blade carrying a substrate and one blade empty to execute a substrate exchange. The transport mechanism 22 may wait at each chamber until an exchange can be accomplished.

Once processing is complete within the process chambers, the transport mechanism 22 may move the substrate W from the last process chamber and transport the substrate W to a cassette within the load lock chambers 16a-b. From the load lock chambers 16a-b, the substrate may move into a factory interface 12. The factory interface 12 generally may operate to transfer substrates between pod loaders 14a-d in an atmospheric pressure clean environment and the load lock chambers 16a-b. The clean environment in factory interface 12 may be generally provided through air filtration processes, such as HEPA filtration, for example. Factory interface 12 may also include a substrate orienter/aligner that may be used to properly align the substrates prior to processing. At least one substrate robot, such as robots 18a-b, may be positioned in factory interface 12 to transport substrates between various positions/locations within factory interface 12 and to other locations in communication therewith. Robots 18a-b may be configured to travel along a track system within factory interface 12 from a first end to a second end of the factory interface 12.

The processing system 10 may further include an integrated metrology chamber 28 to provide control signals, which may provide adaptive control over any of the processes being performed in the processing chambers. The integrated metrology chamber 28 may include any of a variety of metrological devices to measure various film properties, such as thickness, roughness, composition, and the metrology devices may further be capable of characterizing grating parameters such as critical dimensions, sidewall angle, and feature height under vacuum in an automated manner.

Each of processing chambers 24a-d may be configured to perform one or more process steps in the fabrication of a semiconductor structure, and any number of processing chambers and combinations of processing chambers may be used on multi-chamber processing system 10. For example, any of the processing chambers may be configured to perform a number of substrate processing operations including any number of deposition processes including cyclical layer deposition, atomic layer deposition, chemical vapor deposition, physical vapor deposition, as well as other operations including etch, pre-clean, pre-treatment, post-treatment, anneal, plasma processing, degas, orientation, and other substrate processes. Some specific processes that may be performed in any of the chambers or in any combination of chambers may be metal deposition, surface cleaning and preparation, thermal annealing such as rapid thermal processing, and plasma processing. Any other processes may similarly be performed in specific chambers incorporated into multi-chamber processing system 10, including any process described below, as would be readily appreciated by the skilled artisan.

FIG. 2 illustrates a schematic cross-sectional view of an exemplary processing chamber 100 suitable for patterning a material layer disposed on a substrate 302 in the processing chamber 100. The exemplary processing chamber 100 is suitable for performing a patterning process, although it is to be understood that aspects of the present technology may be performed in any number of chambers, and substrate supports according to the present technology may be included in etching chambers, deposition chambers, treatment chambers, or any other processing chamber. The plasma processing chamber 100 may include a chamber body 105 defining a chamber volume 101 in which a substrate may be processed. The chamber body 105 may have sidewalls 112 and a bottom 118 which are coupled with ground 126. The sidewalls 112 may have a liner 115 to protect the sidewalls 112 and extend the time between maintenance cycles of the plasma processing chamber 100. The dimensions of the chamber body 105 and related components of the plasma processing chamber 100 are not limited and generally may be proportionally larger than the size of the substrate 302 to be processed therein. Examples of substrate sizes include 200 mm diameter, 250 mm diameter, 300 mm diameter and 450 mm diameter, among others, such as display or solar cell substrates as well.

The chamber body 105 may support a chamber lid assembly 110 to enclose the chamber volume 101. The chamber body 105 may be fabricated from aluminum or other suitable materials. A substrate access port 113 may be formed through the sidewall 112 of the chamber body 105, facilitating the transfer of the substrate 302 into and out of the plasma processing chamber 100. The access port 113 may be coupled with a transfer chamber and/or other chambers of a substrate processing system as previously described. A pumping port 145 may be formed through the sidewall 112 of the chamber body 105 and connected to the chamber volume 101. A pumping device may be coupled through the pumping port 145 to the chamber volume 101 to evacuate and control the pressure within the processing volume. The pumping device may include one or more pumps and throttle valves.

A gas panel 160 may be coupled by a gas line 167 with the chamber body 105 to supply process gases into the chamber volume 101. The gas panel 160 may include one or more process gas sources 161, 162, 163, 164 and may additionally include inert gases, non-reactive gases, and reactive gases, as may be utilized for any number of processes. Examples of process gases that may be provided by the gas panel 160 include, but are not limited to, hydrocarbon containing gas including methane, sulfur hexafluoride, silicon chloride, carbon tetrafluoride, hydrogen bromide, hydrocarbon containing gas, argon gas, chlorine, nitrogen, helium, or oxygen gas, as well as any number of additional materials. Additionally, process gasses may include nitrogen, chlorine, fluorine, oxygen, and hydrogen containing gases such as H₂, NH₃, H₂O, H₂O₂, NF₃, HF, F₂, CF₄, CHF₃, C₂F₆, C₂F₄, C₃F₆, C₄F₆, C₄F₈, BrF₃, ClF₃, SF₆, CH₃F, CH₂F₂, BCl₃, PF₃, PH₃, COS, and SO₂, among any number of additional precursors.

Valves 166 may control the flow of the process gases from the sources 161, 162, 163, 164 from the gas panel 160 and may be managed by a controller 165. The flow of the gases supplied to the chamber body 105 from the gas panel 160 may include combinations of the gases form one or more sources. The lid assembly 110 may include a nozzle 114. The nozzle 114 may be one or more ports for introducing the process gases from the sources 161, 162, 164, 163 of the gas panel 160 into the chamber volume 101. After the process gases are introduced into the plasma processing chamber 100, the gases may be energized to form plasma. An antenna 148, such as one or more inductor coils, may be provided adjacent to the plasma processing chamber 100. An antenna power supply 142 may power the antenna 148 through a match circuit 141 to inductively couple energy, such as RF energy, to the process gas to maintain a plasma formed from the process gas in the chamber volume 101 of the plasma processing chamber 100. Alternatively, or in addition to the antenna power supply 142, process electrodes below the substrate 302 and/or above the substrate 302 may be used to capacitively couple RF power to the process gases to maintain the plasma within the chamber volume 101. The operation of the power supply 142 may be controlled by a controller, such as controller 165, that also controls the operation of other components in the plasma processing chamber 100.

A substrate support pedestal 135 may be disposed in the chamber volume 101 to support the substrate 302 during processing. The substrate support pedestal 135 may include an electrostatic chuck (“ESC”) 122 for holding the substrate 302 during processing. The electrostatic chuck 122 may use the electrostatic attraction to hold the substrate 302 to the substrate support pedestal 135. The ESC 122 may be powered by an RF power supply 125 integrated with a match circuit 124. The ESC 122 may include an electrode 121 embedded within a dielectric body. The electrode 121 may be coupled with the RF power supply 125 and may provide a bias which attracts plasma ions, formed by the process gases in the chamber volume 101, to the ESC 122 and substrate 302 seated on the pedestal. The RF power supply 125 may cycle on and off, or pulse, during processing of the substrate 302. The ESC 122 may have an isolator 128 for the purpose of making the sidewall of the ESC 122 less attractive to the plasma to prolong the maintenance life cycle of the ESC 122. Additionally, the substrate support pedestal 135 may have a cathode liner 136 to protect the sidewalls of the substrate support pedestal 135 from the plasma gases and to extend the time between maintenance of the plasma processing chamber 100.

Electrode 121 may be coupled with a power source 150. The power source 150 may provide a chucking voltage of about 500 volts to about 15,000 volts to the electrode 121. The power source 150 may also include a system controller for controlling the operation of the electrode 121 by directing a DC current to the electrode 121 for chucking and de-chucking the substrate 302. For example, similar to the RF power supply 125, power supply 150 may provide a bias which attracts plasma ions, formed by the process gases in the chamber volume 101, to the ESC 122 and substrate 302 seated on the pedestal. The power supply 150 may cycle on and off, or pulse, during processing of the substrate 302. In embodiments, the power supply 150 may supply RF power, DC current or voltage for chucking and/or bias, or a combination thereof. In additional embodiments, multiple power supplies may be configured to supply RF power and DC current or voltage for chucking and/or bias. The ESC 122 may include heaters disposed within the pedestal and connected to a power source for heating the substrate, while a cooling base 129 supporting the ESC 122 may include conduits for circulating a heat transfer fluid to maintain a temperature of the ESC 122 and substrate 302 disposed thereon. The ESC 122 may be configured to perform in the temperature range required by the thermal budget of the device being fabricated on the substrate 302. For example, the ESC 122 may be configured to maintain the substrate 302 at a temperature of about −150° C. or lower to about 500° C. or higher depending on the process being performed.

The cooling base 129 may be provided to assist in controlling the temperature of the substrate 302. To mitigate process drift and time, the temperature of the substrate 302 may be maintained substantially constant by the cooling base 129 throughout the time the substrate 302 is in the cleaning chamber. In some embodiments, the temperature of the substrate 302 may be maintained throughout subsequent cleaning processes at temperatures between about −150° C. and about 500° C., although any temperatures may be utilized. A cover ring 130 may be disposed on the ESC 122 and along the periphery of the substrate support pedestal 135. The cover ring 130 may be configured to confine etching gases to a desired portion of the exposed top surface of the substrate 302, while shielding the top surface of the substrate support pedestal 135 from the plasma environment inside the plasma processing chamber 100. Lift pins may be selectively translated through the substrate support pedestal 135 to lift the substrate 302 above the substrate support pedestal 135 to facilitate access to the substrate 302 by a transfer robot or other suitable transfer mechanism as previously described.

The controller 165 may be utilized to control the process sequence, regulating the gas flows from the gas panel 160 into the plasma processing chamber 100, and other process parameters. Software routines, when executed by the CPU, transform the CPU into a specific purpose computer such as a controller, which may control the plasma processing chamber 100 such that the processes are performed in accordance with the present disclosure. The software routines may also be stored and/or executed by a second controller that may be associated with the plasma processing chamber 100.

The chamber discussed previously may be used in performing exemplary methods, including etching methods, although any number of chambers may be configured to perform one or more aspects used in embodiments of the present technology. Turning to FIG. 3, exemplary operations in a method 300 according to embodiments of the present technology are shown. Method 300 may include one or more operations prior to the initiation of the method, including front end processing, deposition, etching, polishing, cleaning, or any other operations that may be performed prior to the described operations. The methods may include a number of optional operations, which may or may not be specifically associated with some embodiments of methods, according to embodiments of the present technology. For example, many of the operations are described in order to provide a broader scope of the processes performed, but are not critical to the technology, or may be performed by alternative methodology as will be discussed further below. Method 300 may describe operations shown schematically in FIGS. 4A-4D, the illustrations of which will be described in conjunction with the operations of method 300. It is to be understood that the figures illustrate only partial schematic views, and a substrate may contain any number of additional materials and features having a variety of characteristics and aspects as illustrated in the figures.

Method 300 may or may not involve optional operations to develop the semiconductor structure to a particular fabrication operation. It is to be understood that method 300 may be performed on any number of semiconductor structures 400 or substrates 405, as illustrated in FIG. 4A, including exemplary structures on which a silicon-and-nitrogen-containing material, such as silicon nitride, etching operation may be performed. As illustrated in FIG. 4A, substrate 405 may include a layer of silicon-and-nitrogen-containing material 410, such as silicon nitride. Additionally, to allow for one or more holes or trenches to be formed through the layer of the silicon-and-nitrogen-containing material 410, a mask material 415 may be formed on the silicon-and-nitrogen-containing material 410. The mask material 415 may be patterned to form one or more apertures 420, exposing a portion the underlying silicon-and-nitrogen-containing material 410. Although only a single aperture 420 is illustrated, it is to be understood that exemplary structure 400 may include any number of apertures across the substrate 405. Some or all of these operations may be performed in chambers or system tools as previously described, or may be performed in different chambers on the same system tool, which may include the chamber in which the operations of method 300 are performed.

Method 300 may be performed to etch or otherwise remove portions of the silicon-and-nitrogen-containing material 410, which may form holes or trenches in the structure 400 as illustrated. The method 300 may be performed to facilitate control of the profile through the structure, and improve etch characteristics, such as uniformity of the holes or trenches as the etch progresses into silicon-and-nitrogen-containing material 410. Method 300 may include flowing a fluorine-containing precursor into a processing region of the semiconductor processing chamber in which the substrate is maintained at operation 305. Plasma effluents of the fluorine-containing precursor may be formed at optional operation 310. The fluorine-containing precursor, or plasma effluents thereof if formed, may contact the substrate at operation 315, and may form a fluorinated portion of the silicon-and-nitrogen-containing material 410.

In embodiments, method 300 may include halting a flow of the fluorine-containing precursor after a first period of time at optional operation 320. Method 300 may also include purging the processing region with a purge precursor after halting the flow of the fluorine-containing precursor. After fluorinating a portion of the silicon-and-nitrogen-containing material 410, and optionally halting the flow of the fluorine-containing precursor and/or purging the processing region, method 300 may include flowing an inert precursor into the processing region of the semiconductor processing chamber at operation 325. Plasma effluents of the inert precursor may be formed at operation 330. As illustrated in FIG. 4B, the plasma effluents of the inert precursor may contact the substrate at operation 335, and may remove the fluorinated portion of the silicon-and-nitrogen-containing material 410. Removing the fluorinated portion of the silicon-and-nitrogen-containing material 410 may begin to form a hole or trench 425 in the silicon-and-nitrogen-containing material 410. The hole or trench 425 may be in alignment with the aperture 420 in the mask material 415. Again, although only a single hole or trench 425 is illustrated, it is to be understood that exemplary structure 400 may include any number of holes or trenches across the substrate 405.

As illustrated in FIGS. 4C-4D, the operations of method 300 may be repeated for a second cycle and may be repeated for any number of cycles. The number of cycles may be dependent on a desired depth of the hole or trench 425. In embodiments, the depth of the hole or trench 425 may extend through an entire thickness of the silicon-and-nitrogen-containing material 410, which may ultimately expose substrate 405.

Fluorine-containing precursors flowed at operation 305 may include hydrogen fluoride (HF), nitrogen trifluoride (NF₃), diatomic fluorine (F₂), bromine trifluoride (BrF₃), chlorine trifluoride (ClF₃), sulfur hexafluoride (SF₆), xenon difluoride (XeF₂), carbon tetrafluoride (CF₄), or any organofluoride, or any other fluorine-containing precursor used or useful in semiconductor processing. In some embodiments, the fluorine-containing precursor may include hydrogen. The fluorine-containing precursor may also be flowed with any number of additional precursors or carrier gases including nitrogen, argon, helium, or any number of additional materials, although in some embodiments the precursors may be limited to control side reactions or other aspects that may impact the fluorination. In some embodiments, to limit and/or prevent the formation of polymeric material in the hole or trench 425, the processing region may be maintained carbon-free while flowing the fluorine-containing precursor and contacting the substrate with the fluorine-containing precursor. As such, some embodiments may utilize fluorine-containing precursors that are carbon-free. By maintaining the processing region free of carbon, carbon-based polymeric material may not form within the hole or trench 425.

The flow rate of the fluorine-containing precursor may be less than or about 500 sccm, and may be less than or about 475 sccm, less than or about 450 sccm, less than or about 425 sccm, less than or about 400 sccm, less than or about 375 sccm, less than or about 350 sccm, less than or about 325 sccm, less than or about 300 sccm, less than or about 275 sccm, less than or about 250 sccm, or less. At flow rates greater than, for example, 500 sccm, excessive fluorine may be present and may result in excessive or uncontrolled etching. For example, excessive fluorine may result in lateral etching that may impact uniformity of the fluorination and subsequent etch.

In embodiments, a plasma may not be formed of the fluorine-containing precursor.

Instead, a thermal operation may proceed where the fluorine-containing precursor may condense on the silicon-and-nitrogen-containing material 410. As such, in some embodiments, the processing region may be maintained plasma-free while flowing the fluorine-containing precursor and contacting the substrate 405 and/or silicon-and-nitrogen-containing material 410 with the fluorine-containing precursor.

However, as previously discussed, it is also contemplated that plasma effluents of the fluorine-containing precursor may be formed at optional operation 310. The plasma power used to form plasma effluents of the fluorine-containing precursor may be a relatively low plasma power. The relatively low plasma power may allow for controlled dissociation of the fluorine-containing precursor. At higher plasma powers, increased amounts of fluorine radicals may be present and the etch amount per cycle may increase due to increased fluorination of the silicon-and-nitrogen-containing material 410. Accordingly, the plasma effluents of the fluorine-containing precursor may be formed at less than or about 1,500 W, and may be formed at less than or about 1,400 W, less than or about 1,300 W, less than or about 1,250 W, less than or about 1,200 W, less than or about 1,100 W, less than or about 1,000 W, or less. However, very low plasma powers may result in low plasma density. Therefore, the plasma effluents of the fluorine-containing precursor may be formed at greater than or about 500 W, and may be formed at greater than or about 600 W, greater than or about 700 W, greater than or about 750 W, greater than or about 800 W, greater than or about 900 W, greater than or about 1,000 W, or more.

As previously discussed, the contacting at operation 315 may form a fluorinated portion of the silicon-and-nitrogen-containing material 410. For example, the contacting may form a silicon-nitrogen-and-fluorine-containing material. The fluorinated portion of the silicon-and-nitrogen-containing material 410 may be a reactive layer that may be subsequently removed by contacting the substrate with plasma effluents of the inert precursor.

The fluorination operations may be continued for a first period of time. The first period of time may be sufficient to produce a reactive layer in the silicon-and-nitrogen-containing material 410, or fluorinated portion of the silicon-and-nitrogen-containing material 410, while limiting residence time that may begin to saturate the fluorination. For example, the first period of time may be greater than or about 1 second, and may be greater than or about 2 seconds, greater than or about 3 seconds, greater than or about 4 seconds, greater than or about 5 seconds, greater than or about 10 seconds, greater than or about 15 seconds, greater than or about 20 seconds, greater than or about 25 seconds, greater than or about 30 seconds, or more. However, at increased periods of time, the fluorine may no longer be able to penetrate the silicon-and-nitrogen-containing material 410 and additional residence time may not realize an increased benefit. Accordingly, to maintain efficiency, the first period of time may be less than or about 5 minutes, and may be less than or about 3 minutes, less than or about 1 minute, less than or about 55 seconds, less than or about 50 seconds, less than or about 45 seconds, less than or about 40 seconds, less than or about 35 seconds, less than or about 30 seconds, or less.

Subsequent the first period of time, the flow of the fluorine-containing precursor may be halted. A purge may then be performed, which may remove residual etchant materials, etch byproducts, or other materials from the processing region. The purge may be performed with any number of materials that may be chemically inert, such as nitrogen or noble gases, which may be used to purge the processing region of the semiconductor processing chamber. The purging process may improve throughput by expediting removal of byproducts and/or reduce the residence time of these materials within the processing region. For example, if fluorine-containing precursor were still present in the processing region, the subsequent plasma formed of the inert precursor could also form plasma effluents of the fluorine-containing precursor. Plasma effluents of the fluorine-containing precursor could increase the etch rate and even undesirably etch other materials on the substrate 405.

Inert precursors flowed at operation 325 may include nitrogen, argon, helium, xenon, or other noble gases, or any chemically inert material used or useful in semiconductor processing. The flow rate of the inert precursor may be less than or about 500 sccm, and may be less than or about 475 sccm, less than or about 450 sccm, less than or about 425 sccm, less than or about 400 sccm, less than or about 375 sccm, less than or about 350 sccm, less than or about 325 sccm, less than or about 300 sccm, less than or about 275 sccm, less than or about 250 sccm, or less.

The plasma power used to form plasma effluents of the inert precursor may be similar to the plasma power used at optional operation 310 and may be a relatively low plasma power. By utilizing a relatively low plasma power, a controlled amount of inert radicals may be formed, which may control the etch rate. Conversely, at higher plasma powers, an increased amount of inert radicals may be performed (similar to the fluorine-containing precursor), resulting in a faster etch. As such, the plasma effluents of the inert precursor may be formed at less than or about 1,500 W, and may be formed at less than or about 1,400 W, less than or about 1,300 W, less than or about 1,250 W, less than or about 1,200 W, less than or about 1,100 W, less than or about 1,000 W, or less. Similarly, the plasma effluents of the inert precursor may be formed at greater than or about 500 W, and may be formed at greater than or about 600 W, greater than or about 700 W, greater than or about 750 W, greater than or about 800 W, greater than or about 900 W, greater than or about 1,000 W, or more.

Further, to reduce the effective plasma power, the source power used to form plasma effluents of the inert precursor may be pulsed or discontinuous. In embodiments, a duty cycle of the plasma power may be between about 5% and about 95%, such as greater than or about 10%, greater than or about 20%, greater than or about 30%, greater than or about 40%, greater than or about 50%, greater than or about 60%, greater than or about 70%, greater than or about 80%, greater than or about 90%, or more.

While forming the plasma effluents of the inert precursor at operation 330 and/or while contacting the substrate with the plasma effluents of the inert precursor at operation 335, a bias power may be applied. The bias power, which may be a voltage applied to the pedestal or substrate support, may increase directionality of the plasma effluents of the inert precursor. The increased directionality may draw the plasma effluents of the inert precursor fluorinated portion of the silicon-and-nitrogen-containing material 410. Accordingly, the plasma effluents of the inert precursor may bombard and remove the fluorinated portion of the silicon-and-nitrogen-containing material 410. In embodiments, the bias power applied may be greater than or about 5 V, and may be applied at greater than or about 10 V, greater than or about 20 V, greater than or about 30 V, greater than or about 40 V, greater than or about 50 V, greater than or about 60 V, greater than or about 70 V, greater than or about 80 V, greater than or about 90 V, greater than or about 100 V, or more. While the bias power is discussed as being provided as a voltage to the pedestal or substrate support, the bias power may additionally or alternatively be a frequency, such as a 2 MHz frequency, applied to the pedestal or substrate support. At higher bias powers, the bombardment may increase and materials on substrate 405 or in structure 400 may begin to sputter. Accordingly, the bias power applied may be less than or about 250 V, and may be formed at less than or about 225 V, less than or about 200 V, less than or about 175 V, less than or about 150 V, less than or about 140 V, less than or about 130 V, less than or about 125 V, less than or about 120 V, less than or about 115 V, less than or about 110 V, or less.

Similar to the plasma power, the bias power may be continuous or may be pulsed or discontinuous to limit the effective bias power. In embodiments, a power-on-time of the bias power may be between about 5% and about 95%, such as less than or about 90%, less than or about 80%, less than or about 70%, less than or about 60%, less than or about 50%, less than or about 40%, less than or about 30%, less than or about 20%, less than or about 10%, or less.

As previously discussed, the contacting at operation 335 may remove the fluorinated portion of the silicon-and-nitrogen-containing material 410. For example, the contacting may bombard the structure 400 and substrate 405 with plasma effluents of the inert precursor. This bombardment and resultant physical interaction may etch the fluorinated portion of the silicon-and-nitrogen-containing material 410. More specifically, ion-driven desorption may cause the fluorinated portion of the silicon-and-nitrogen-containing material 410 to be removed.

The contacting with the inert plasma may be continued for a second period of time. The second period of time may be sufficient to remove reactive layer in the silicon-and-nitrogen-containing material 410, or fluorinated portion of the silicon-and-nitrogen-containing material 410, while limiting residence time that may begin to unnecessarily bombard the substrate 405. In some embodiments, the second period of time may be less than the first period of time. However, it is also contemplated that the second period of time may be equal to or longer than the first period of time. For example, the second period of time may be greater than or about 1 second, and may be greater than or about 2 seconds, greater than or about 3 seconds, greater than or about 4 seconds, greater than or about 5 seconds, greater than or about 10 seconds, greater than or about 15 seconds, greater than or about 20 seconds, greater than or about 25 seconds, greater than or about 30 seconds, or more. However, at increased periods of time, the reactive layer in the silicon-and-nitrogen-containing material 410, or fluorinated portion of the silicon-and-nitrogen-containing material 410, may be removed and additional time may only bombard material that is to be maintained on the substrate 405 (or non-fluorinated portions of the silicon-and-nitrogen-containing material 410). Accordingly, to maintain efficiency, the second period of time may be less than or about 5 minutes, and may be less than or about 3 minutes, less than or about 1 minute, less than or about 55 seconds, less than or about 50 seconds, less than or about 45 seconds, less than or about 40 seconds, less than or about 35 seconds, less than or about 30 seconds, or less.

In embodiments, a thickness of the silicon-and-nitrogen-containing material 410 that may be fluorinated and subsequently removed may be less than or about 15 nm per cycle, and may be less than or about 12.5 nm, less than or about 10 nm, less than or about 9 nm, less than or about 8 nm, less than or about 7 nm, less than or about 6 nm, less than or about 5 nm, less than or about 4 nm, less than or about 3 nm, less than or about 2 nm, less than or about 1 nm, or less. The thickness of the silicon-and-nitrogen-containing material 410 that may be fluorinated and subsequently removed may be limited by the ability of the fluorine-containing precursor to diffuse through the silicon-and-nitrogen-containing material 410. For example, longer periods of time exposing the silicon-and-nitrogen-containing material 410 to the fluorine-containing precursor may increase the thickness, but the effect of fluorine-containing precursor may be limited at a certain depth of the silicon-and-nitrogen-containing material 410.

By performing an amount of fluorination followed by an amount of removal or etch, a controlled directional etch of the silicon-and-nitrogen-containing material 410 may be performed. As illustrated in FIGS. 4C-4D, to further facilitate directional etching, the present technology may be performed in a number of cycles to allow efficient fluorination and subsequent removal of the silicon-and-nitrogen-containing material 410. In some embodiments, method 300 may include repeating the operations 305-335 for at least two cycles, and may include repeating the operations 305-335 for at least three cycles, at least four cycles, at least five cycles, at least ten cycles, at least fifteen cycles, at least twenty cycles, or more. It is contemplated that the operations 305-335 of method 300 may be repeated any number of times depending on desired depth of the hole or trench 425 to be etched.

Process conditions may also impact the operations performed in method 300. Each of the operations of method 300 may be performed during a constant temperature in embodiments, while in some embodiments the temperature may be adjusted during different operations. Temperatures may be maintained in any range, however, at lower temperatures, increased condensation of the fluorine-containing precursor may result and a thicker reactive layer or fluorinated portion of the silicon-and-nitrogen-containing material 410 may be formed. Conversely, at higher temperatures, a thinner reactive layer or fluorinated portion of the silicon-and-nitrogen-containing material 410 may result. As amount or thicknesses of fluorination decreases, throughput may decrease. Accordingly, in some embodiments any or all operations of the method 300 may performed at a chamber operating temperature of less than or about 20° C., and may be performed at a chamber operating temperature of less than or about 10° C., less than or about 0° C., less than or about −10° C., less than or about −20° C., less than or about −30° C., less than or about −40° C., less than or about −50° C., less than or about −60° C., less than or about −70° C., less than or about −80° C., or less.

Each of the operations of method 300 may be performed during a constant pressure in embodiments, while in some embodiments the pressure may be adjusted during different operations. Pressures may be maintained in any range, however, at reduced pressures, condensation of the fluorine-containing precursor on the silicon-and-nitrogen-containing material 410 may reduce. As such, increased pressures may increase condensation of the fluorine-containing precursor on the silicon-and-nitrogen-containing material 410. However, at increased pressures, increased ion collision may occur in the plasma effluents of the inert precursor, resulting in reduced directionality and increased sidewall etch of the hole or trench 425. Accordingly, in some embodiments any or all operations of the method 300 may performed at a chamber operating pressure of less than or about 1 Torr, and may be performed at a chamber operating pressure of less than or less than or about 900 mTorr, less than or about 800 mTorr, less than or about 700 mTorr, less than or about 600 mTorr, less than or about 500 mTorr, less than or about 400 mTorr, less than or about 300 mTorr, less than or about 200 mTorr, less than or about 100 mTorr, less than or about 75 mTorr, less than or about 50 mTorr, less than or about 40 mTorr, less than or about 30 mTorr, less than or about 25 mTorr, or less. Additionally, greater than or about 5 mTorr, and may be performed at a chamber operating pressure of greater than or about 10 mTorr, greater than or about 15 mTorr, greater than or about 20 mTorr, greater than or about 25 mTorr, greater than or about 30 mTorr, greater than or about 35 mTorr, greater than or about 40 mTorr, greater than or about 45 mTorr, greater than or about 50 mTorr, greater than or about 55 mTorr, greater than or about 60 mTorr, or more. In some embodiments, it is contemplated that the chamber operating pressure may be reduced between contacting the substrate with the fluorine-containing precursor at operation 315 and contacting the substrate with the plasma effluents of the inert precursor at operation 335.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology. Additionally, methods or processes may be described as sequential or in steps, but it is to be understood that the operations may be performed concurrently, or in different orders than listed.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a precursor” includes a plurality of such precursors, and reference to “the layer” includes reference to one or more layers and equivalents thereof known to those skilled in the art, and so forth. “About” and/or “approximately” as used herein when referring to a measurable value such as an amount, a temporal duration, and the like, encompasses variations of ±20% or ±10%, ±5%, or ±0.1% from the specified value, as such variations are appropriate to in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or ±0.1% from the specified value, as such variations are appropriate to in the context of the systems, devices, circuits, methods, and other implementations described herein.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
flowing a fluorine-containing precursor into a processing region of a semiconductor processing chamber, wherein a substrate is positioned within the processing region, and wherein the substrate comprises a layer of a silicon-and-nitrogen-containing material;
contacting the substrate with the fluorine-containing precursor, wherein the contacting forms a fluorinated portion of the silicon-and-nitrogen-containing material;
flowing an inert precursor into the processing region of the semiconductor processing chamber;
forming plasma effluents of the inert precursor; and
contacting the substrate with the plasma effluents of the inert precursor, wherein the contacting removes the fluorinated portion of the silicon-and-nitrogen-containing material, and wherein the method is performed at a chamber operating temperature of less than or about 20° C.

2. The semiconductor processing method of claim 1, wherein the fluorine-containing precursor comprises hydrogen fluoride (HF).

3. The semiconductor processing method of claim 1, wherein the processing region is maintained carbon-free while flowing the fluorine-containing precursor and contacting the substrate with the fluorine-containing precursor.

4. The semiconductor processing method of claim 1, wherein the substrate further comprises a patterned mask material overlying the layer of the silicon-and-nitrogen-containing material.

5. The semiconductor processing method of claim 1, further comprising:
prior to flowing the inert precursor, halting a flow of the fluorine-containing precursor after a first period of time; and
purging the processing region with a purge precursor.

6. The semiconductor processing method of claim 5, wherein the first period of time is less than or about 5 minutes.

7. The semiconductor processing method of claim 1, wherein the processing region is maintained plasma-free while flowing the fluorine-containing precursor and contacting the substrate with the fluorine-containing precursor.

8. The semiconductor processing method of claim 1, wherein the inert precursor comprises argon.

9. The semiconductor processing method of claim 1, further comprising:
applying a bias power while contacting the substrate with the plasma effluents of the inert precursor.

10. The semiconductor processing method of claim 9, wherein the bias power is less than or about 150 V.

11. The semiconductor processing method of claim 1, wherein the method is performed at a chamber operating pressure of less than or about 1 Torr.

12. The semiconductor processing method of claim 1, wherein the method is performed at a chamber operating temperature of less than or about −50° C.

13. The semiconductor processing method of claim 1, further comprising:
repeating the operations for at least two cycles.

14. A semiconductor processing method comprising:
i) flowing a fluorine-containing precursor into a processing region of a semiconductor processing chamber, wherein a substrate is positioned within the processing region, and wherein the substrate comprises a layer of a silicon-and-nitrogen-containing material;
ii) contacting the layer of the silicon-and-nitrogen-containing material with the fluorine-containing precursor, wherein the contacting forms a fluorinated portion of the layer of the silicon-and-nitrogen-containing material, and wherein contacting is performed plasma-free;
iii) halting a flow of the fluorine-containing precursor;
iv) flowing an inert precursor into the processing region of the semiconductor processing chamber;
v) forming plasma effluents of the inert precursor;
vi) contacting the substrate with the plasma effluents of the inert precursor, wherein the contacting removes the fluorinated portion of the layer of the silicon-and-nitrogen-containing material; and
vii) repeating operations i) through vi) for at least a second cycle.

15. The semiconductor processing method of claim 14, wherein the fluorine-containing precursor further comprises hydrogen.

16. The semiconductor processing method of claim 14, wherein a flow rate of the fluorine-containing precursor is less than or about 500 sccm.

17. The semiconductor processing method of claim 14, wherein operations i) through vi) are repeated for at least ten cycles.

18. The semiconductor processing method of claim 14, wherein the method is performed at a chamber operating temperature of less than or about −40° C.

19. A semiconductor processing method comprising:
flowing a fluorine-containing precursor into a processing region of a semiconductor processing chamber, wherein a substrate is positioned within the processing region, and wherein the substrate comprises a layer of a silicon-and-nitrogen-containing material;
contacting the substrate with the fluorine-containing precursor for a first period of time, wherein the contacting forms a fluorinated portion of the silicon-and-nitrogen-containing material, and wherein the fluorinated portion of the silicon-and-nitrogen-containing material is characterized by a thickness of greater than or about 50 nm;
halting a flow of the fluorine-containing precursor into the processing region subsequent the first period of time;
flowing an inert precursor into the processing region of the semiconductor processing chamber;
forming plasma effluents of the inert precursor; and
contacting the substrate with the plasma effluents of the inert precursor for a second period of time, wherein the contacting removes the fluorinated portion of the silicon-and-nitrogen-containing material.

20. The semiconductor processing method of claim 19, wherein the first period of time is less than or about 60 seconds and the second period of time is less than or about 30 seconds.
